(19) United States
(12) Patent Application Publication
(10) Pub. No.: US 2015/0108457 A1
(43) Pub. Date: Apr. 23, 2015

(54) RESIN COMPOSITION, METHOD OF MANUFACTURING RESIN COMPOSITION, SUBSTRATE, METHOD OF MANUFACTURING ELECTRONIC DEVICE AND ELECTRONIC DEVICE

(71) Applicants: AKRON POLYMER SYSTEMS INC., Akron, OH (US); SUMITOMO BAKELITE COMPANY LIMITED, Shinagawa-ku (JP)

(72) Inventors: Limin Sun, Copley, OH (US); Dong Zhang, Uniontown, OH (US); Jiaokai Jing, Uniontown, OH (US); Frank W. Harris, Boca Raton, FL (US); Hideo Umeda, Kobe City (JP); Ritsuya Kawasaki, Kobe City (JP); Jun Okada, Kobe City (JP); Mizuho Inoue, Kobe City (JP); Manabu Naito, Kobe City (JP)

(73) Assignees: AKRON POLYMER SYSTEMS INC., Akron, OH (US); SUMITOMO BAKELITE COMPANY LIMITED, Shinagawa-ku (JP)

(21) Appl. No.: 14/520,921

(22) Filed: Oct. 22, 2014

Related U.S. Application Data
(60) Provisional application No. 61/894,735, filed on Oct. 23, 2013.

(51) Int. Cl. H01L 51/00; H01L 51/56; C08L 77/06

(52) U.S. Cl. CPC H01L 51/0097; C08L 77/06; H01L 51/56; H01L 2251/558; H01L 2251/5338
USPC 257/40; 524/879; 428/474.4; 428/335; 438/46

(57) ABSTRACT

Provided are a resin composition and a substrate that are capable of being used for manufacturing an electronic device including a transparent resin film having an excellent display property, a method of manufacturing such a resin composition and a method of manufacturing the electronic device using such a substrate and the electronic device. The resin composition of the present invention contains an aromatic polyamide, an aromatic multifunctional compound having two or more functional groups including a carboxyl group or an amino group, and a solvent dissolving the aromatic polyamide.

### CROSS-REFERENCE TO RELATED APPLICATIONS

The present application is based upon and claims the benefit of priority to U.S. Application No. 61/894,735, filed Oct. 23, 2013, the entire contents of which are incorporated herein by reference.

### TECHNICAL FIELD

The present invention relates to a resin composition, a method of manufacturing a resin composition, a substrate, a method of manufacturing an electronic device and an electronic device.

### BACKGROUND ART

In a display device (electronic device) such as an organic EL (electroluminescence) display device and a liquid crystal display device, transparency is required in a substrate used in the display device. Therefore, it is known to use a transparent resin film as the substrate used in the display device (for example, the patent document 1).

The transparent resin film used as the substrate generally has flexibility (flexible characteristics). Therefore, the transparent resin film is first formed (film-formed) on a first surface of a plate-like base member and then each element to be provided in the display device is formed on the transparent resin film. Finally, by peeling off the transparent resin film from the base member, it is possible to manufacture the display device including the transparent resin film and the elements.

In the method of manufacturing such a display device, the peeling-off of the transparent resin film from the base member is achieved by irradiating the transparent resin film with light such as laser light from a side of a second surface of the base member opposite to the first surface on which the transparent resin film is provided. The irradiation of the light results in the peeling-off of the transparent resin film from the base member in an interface between the base member and the transparent resin film.

As described above, each element to be provided in the display device is formed on the transparent resin film. At the time of forming each element, a liquid material containing a solvent is used. A method of forming each element on the transparent resin film may contain a step of forming at least a part of each element of the display device by supplying the liquid material onto the transparent resin film and then drying the liquid material on the transparent resin.

Therefore, depending on the kind of the solvent contained in the liquid material, a constituent material of the transparent resin film is altered or deteriorated by supplying the liquid material onto the transparent resin film. Due to the alteration or the deterioration of the constituent material of the transparent resin film, a problem in that adverse effects are given to a display property of the display device occurs.

The patent document 1: WO 2004/039863

### SUMMARY OF THE INVENTION

It is an object of the present invention to provide a resin composition and a substrate that are capable of being used for manufacturing an electronic device including a transparent resin film having an excellent display property. It is another object of the present invention to provide a method of manufacturing such a resin composition, a method of manufacturing the electronic device using such a substrate and the electronic device.

In order to achieve the objects described above, the present invention includes the following features (1) to (25).

(1) A resin composition comprising:

an aromatic polyamide;

an aromatic multifunctional compound having two or more functional groups including a carboxyl group or an amino group; and

a solvent dissolving the aromatic polyamide.

(2) In the above resin composition according to the present invention, it is preferred that each of the functional groups of the aromatic multifunctional compound is the carboxyl group.

(3) In the above resin composition according to the present invention, it is also preferred that the aromatic multifunctional compound is selected from the group consisting of compounds represented by the following general formulas (A) to (C):

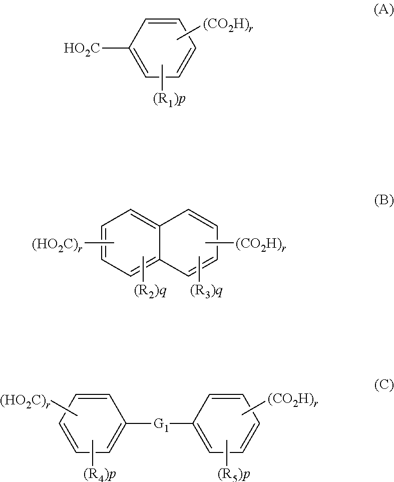

where r=1 or 2, p=3 or 4, q=2 or 3, each of R₁, R₂, R₃, R₄ and R₅ is selected from the group consisting of a hydrogen atom, a halogen (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).

(4) In the above resin composition according to the present invention, it is also preferred that the aromatic multifunctional compound is trimeric acid.

(5) In the above resin composition according to the present invention, it is also preferred that the aromatic polyamide is a wholly aromatic polyamide.

(6) In the above resin composition according to the present invention, it is also preferred that the aromatic polyamide has a repeating unit represented by the following general formula (I)

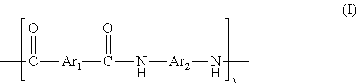

where x is an integral number of 1 or more, Ar₁ is represented by the following general formula (II), (III) or (IV)

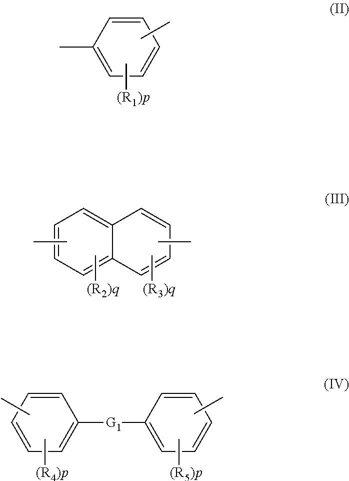

(where p=4; q=3; each of R₁, R₂, R₃, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), and Are is represented by the following general formula (V) or (VI)

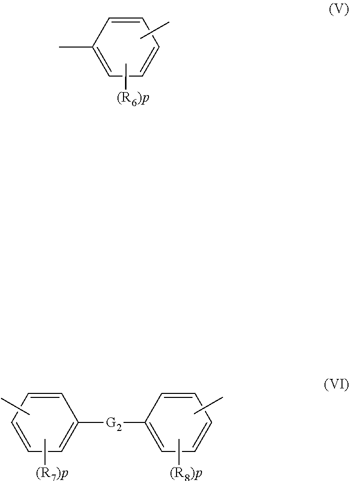

(where p=4; each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₂ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, a SO₂ group, a Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

(7) In the above resin composition according to the present invention, it is also preferred that the resin composition is used to form a layer, and a total light transmittance of the layer in a wavelength of 355 nm is 10% or less.

(8) In the above resin composition according to the present invention, it is also preferred that the aromatic polyamide contains a naphthalene structure.

(9) In the above substrate according to the present invention, it is preferred that at least one terminal of the aromatic polyamide is end-capped.

(10) In the above substrate according to the present invention, it is also preferred that the solvent is a polar solvent.

(11) In the above substrate according to the present invention, it is also preferred that the solvent is an organic solvent and/or an inorganic solvent.

(12) In the above substrate according to the present invention, it is also preferred that the resin composition further contains an inorganic filler.

(13) A method of manufacturing a resin composition, comprising:

mixing one or more aromatic diamines with a solvent to obtain a mixture;

reacting an aromatic diacid dichloride with the aromatic diamines by adding the aromatic diacid dichloride into the mixture to produce a solution containing an aromatic polyamide and hydrochloric acid;

removing the hydrochloric acid from the solution; and

adding an aromatic multifunctional compound having two or more functional groups including a carboxyl group or an amino group into the solution to manufacture the resin composition.

(14) A substrate used for forming an electronic element thereon, comprising:

a plate-like base member having a first surface and a second surface opposite to the first surface; and

an electronic element formation layer provided at a side of the first surface of the base member and configured to be capable of forming the electronic element on the electronic element formation layer,

wherein the electronic element formation layer contains a reactant obtained by reacting an aromatic polyamide with an aromatic multifunctional compound having two or more functional groups including a carboxyl group or an amino group.

(15) In the above substrate according to the present invention, it is preferred that the electronic element formation layer has solvent resistance.

(16) In the above substrate according to the present invention, it is also preferred that a coefficient of thermal expansion (CTE) of the electronic element formation layer is 100 ppm/K or less.

(17) In the above substrate according to the present invention, it is also preferred that an average thickness of the electronic element formation layer is in the range of 1 to 50 μm.

(18) In the above substrate according to the present invention, it is also preferred that the electronic element is an organic EL element.

(19) A method of manufacturing an electronic device, comprising:

preparing a substrate, the substrate including,
a plate-like base member having a first surface and a second surface opposite to the first surface, and
an electronic element formation layer provided at a side of the first surface of the base member,
wherein the electronic element formation layer contains a reactant obtained by reacting an aromatic polyamide with an aromatic multifunctional compound having two or more functional groups including a carboxyl group or an amino group;

forming the electronic element on a surface of the electronic element formation layer opposite to the base member;

forming a cover layer so as to cover the electronic element;

irradiating the electronic element formation layer with light to thereby peel off the electronic element formation layer from the base member in an interface between the base member and the electronic element formation layer; and

separating the electronic device including the electronic element, the cover layer and the electronic element formation layer from the base member.

(20) In the above method of manufacturing the electronic device according to the present invention, it is preferred that the electronic element formation layer has solvent resistance.

(21) In the above method of manufacturing the electronic device according to the present invention, it is also preferred that a coefficient of thermal expansion (CTE) of the electronic element formation layer is 100 ppm/K or less.

(22) In the above method of manufacturing the electronic device according to the present invention, it is also preferred that an average thickness of the electronic element formation layer is in the range of 1 to 50 μm.

(23) In the above method of manufacturing the electronic device according to the present invention, it is also preferred that the aromatic multifunctional compound is selected from the group consisting of compounds represented by the following general formulas (A) to (C):

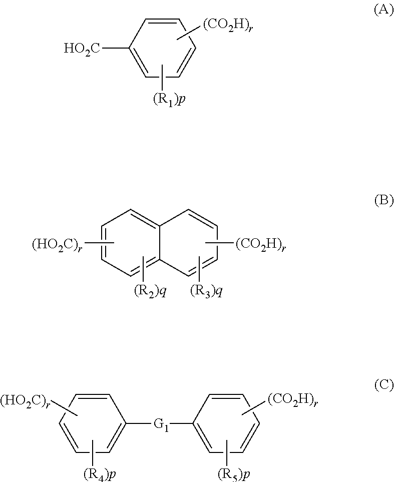

where r=1 or 2, p=3 or 4, q=2 or 3, each of R₁, R₂, R₃, R₄ and R₅ is selected from the group consisting of a hydrogen atom, a halogen (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).

(24) In the above method of manufacturing the electronic device according to the present invention, it is also preferred that the aromatic polyamide has a repeating unit represented by the following general formula (I)

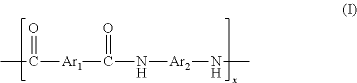

where x is an integral number of 1 or more, Ar₁ is represented by the following general formula (II), (III) or (IV):

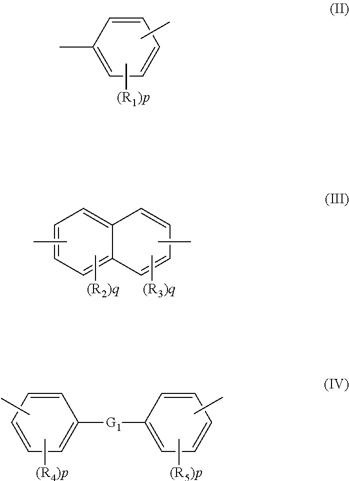

(where p=4; q=3; each of R₁, R₂, R₃, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), and Are is represented by the following general formula (V) or (VI)

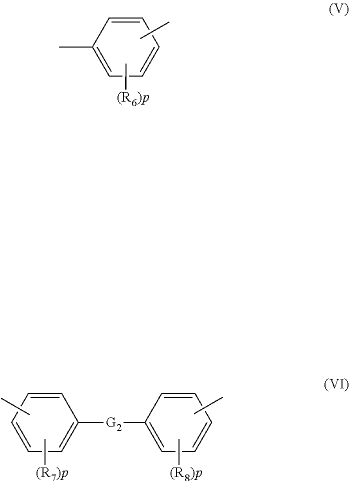

(where p=4; each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₂ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, a SO₂ group, a Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

(25) An electronic device manufactured by using the above method of manufacturing the electronic device according to the present invention.

According to the present invention, it is possible to form a layer having excellent solvent resistance by using the resin composition containing the aromatic polyamide, the aromatic multifunctional compound having the two or more functional groups including the carboxyl group or the amino group, and the solvent dissolving the aromatic polyamide. This layer formed by using the resin composition is used as the electronic element formation layer provided in the electronic device. The electronic element formation layer is provided on a first surface of the base member so as to contact with the base member. Further, each element to be provided in the electronic device is formed on the electronic element formation layer by using a liquid material containing a solvent. By using the layer formed of the resin composition of the present invention as the electronic element formation layer, it is possible to appropriately prevent or suppress alteration or deterioration of the electronic element formation layer which would be caused by a contact of the solvent contained in the liquid material with the electronic element formation layer. Therefore, it is possible to reliably prevent a display property of the display device from being adversely affected by the contact of the solvent contained in the liquid material with the electronic element formation layer.

### BRIEF DESCRIPTION OF THE DRAWINGS

FIG. 1 is a vertical sectional view which shows an embodiment of an organic electroluminescence display device manufactured by applying a method of manufacturing an electronic device of the present invention as a method of manufacturing the organic electroluminescence display device.

FIG. 2 is a sectional view which shows an embodiment of a sensor element manufactured by applying the method of manufacturing the electronic device of the present invention.

FIG. 3 is a vertical sectional view to illustrate the method of manufacturing the organic electroluminescence display device shown in FIG. 1 or the sensor element shown in FIG. 2 (method of manufacturing the electronic device of the present invention).

### MODE FOR CARRYING OUT THE INVENTION

Hereinafter, a resin composition, a method of manufacturing a resin composition, a substrate and a method of manufacturing an electronic device according to the present invention will be described in detail based on the preferred embodiments shown in the accompanying drawings.

First, prior to describing the resin composition, the method of manufacturing the resin composition, the substrate and the method of manufacturing the electronic device according to the present invention, description will be made on an organic electroluminescence display device (organic EL display device) and a sensor element, which are manufactured by using the method of manufacturing the electronic device of the present invention. Namely, the organic electroluminescence display device and the sensor element will be first described as examples of the electronic device of the present invention.

<Organic EL Display Device>

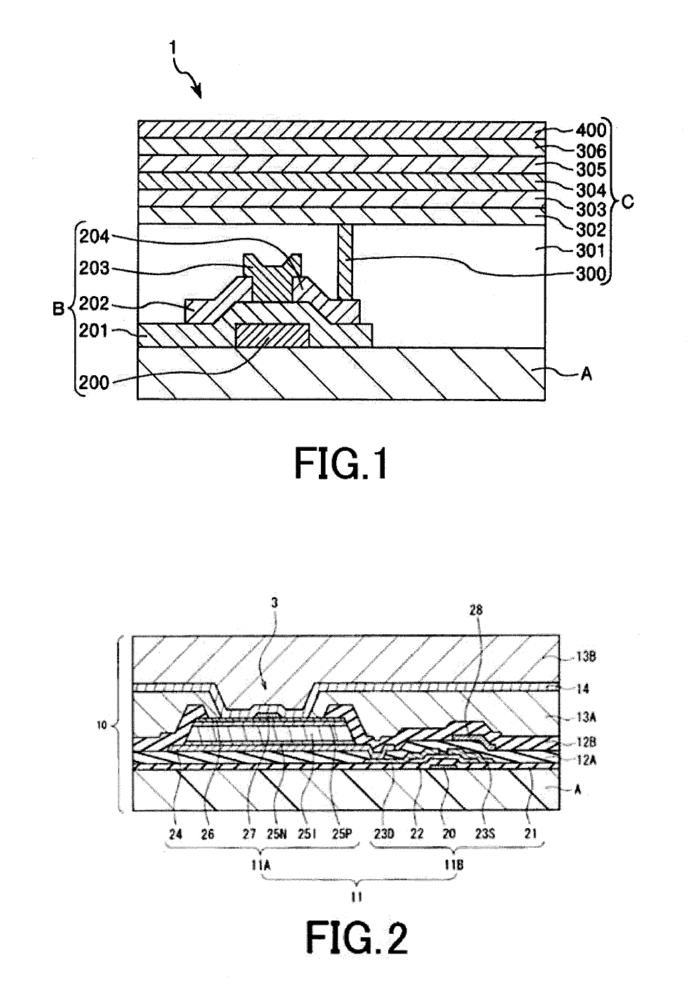

First, the organic electroluminescence display device manufactured by applying the method of manufacturing the electronic device of the present invention will be described. FIG. 1 is a vertical sectional view which shows an embodiment of the organic electroluminescence display device manufactured by applying the method of manufacturing the electronic device of the present invention as a method of manufacturing the organic electroluminescence display device. In the following description, the upper side in FIG. 1 will be referred to as “upper”, and the lower side in FIG. 1 will be referred to as “lower”.

An organic EL display device 1 shown in FIG. 1 includes a resin film (electronic element formation layer) A formed of the resin composition of the present invention, light emitting elements C each provided so as to correspond to each pixel, and a plurality of thin-film transistors B for respectively driving the light emitting elements C.

In this regard, it is to be noted that, in the present embodiment, the organic EL display device 1 is a display panel of a bottom emission type. When the light emitting devices C emit light, the display panel of the bottom emission type can allow the emitted light to transmit through the resin film A to a lower side in FIG. 1 and be extracted from the lower side of the organic EL display device 1.

The thin-film transistors B are provided on the resin film (electronic element formation layer) A so as to correspond to the plurality of light emitting elements C included in the organic EL display device 1. A planarizing layer 301 constituted of an insulating material is formed on the resin film A so as to cover each thin-film transistor B.

Each of the thin-film transistors B includes a gate electrode 200 formed on the resin film A, a gate insulating layer 201 formed so as to cover the gate electrode 200, a source electrode 202 and a drain electrode 204 which are provided on the gate insulating layer 201, and a semiconductor layer 203 constituted of an oxide semiconductor material and formed in a channel region between the source electrode 202 and the drain electrode 204.

Examples of the oxide semiconductor material include a material which includes: at least an oxygen atom (O) as a non-metal element such as a nitrogen atom (N) and the oxygen atom (O); at least one of a boron atom (B), a silicon atom (Si), a germanium atom (Ge), an arsenic atom (As), an antimony atom (Sb), a tellurium atom (Te) and a polonium atom (Po) as a metalloid element; and at least one of an aluminum atom (Al), a zinc atom (Zn), a gallium atom (Ga), a cadmium atom (Cd), an indium atom (In), a tin atom (Sn), a mercury atom (Hg), a thallium atom (Tl), a terbium atom (Tb) and a bismuth atom (Bi) as a metal element. In this regard, it is preferred that the non-metal element is a mixture containing the oxygen atom (O) and the nitrogen atom (N). Further, it is preferred that the oxide semiconductor material contains the indium atom (In), the tin atom (Sn), the silicon atom (Si), the oxygen atom (O) and the nitrogen atom (N) as a main component thereof.

Concrete examples of such an oxide semiconductor material include a material obtained by combining a metal raw material (In₂O₃, SnO₂) with an insulating raw material (Si₃N₄).

Further, the light emitting elements (organic EL element) C are provided on the planarizing layer 301 so as to respectively correspond to the thin-film transistors B.

In this embodiment, each of the light emitting elements C includes an anode 302 and a cathode 306, and further includes a hole transport layer 303, an emission layer 304 and an electron transport layer 305 which are laminated in this order from the anode 302 between the anode 302 and the cathode 306.

Furthermore, the anode 302 of each light emitting element C is electrically connected to the drain electrode 204 of each corresponding thin-film transistor B through a conductive part 300.

In the organic EL display device 1 including the plurality of light emitting elements C having such a configuration, luminescence brightness of each light emitting element C can be controlled by using each corresponding thin-film transistor B. That is, by controlling a voltage to be applied to each light emitting element C, it is possible to control the luminescence brightness of each light emitting device C. By controlling the luminescence brightness of each light emitting element C, it becomes possible for the organic EL display device 1 to perform a full color display. Further, it is also possible to perform a mono color display by synchronously emitting the light from the light emitting elements C at the same time.

Furthermore, in this embodiment, a sealing substrate 400 is formed on each light emitting element C so as to cover it. This makes it possible to ensure airtightness of the light emitting elements C, thereby enabling to prevent oxygen or moisture from penetrating into the light emitting elements C.

<Sensor Element>

Next, the sensor element manufactured by applying the method of manufacturing the electronic device of the present invention will be described. FIG. 2 is a sectional view which shows an embodiment of the sensor element manufactured by applying the method of manufacturing the electronic device of the present invention. In the following description, the upper side in FIG. 2 will be referred to as “upper”, and the lower side in FIG. 2 will be referred to as “lower”.

The sensor element of the present invention is, for example, a sensor element that can be used in an input device. In one or plurality of embodiments of this discloser, the sensor element of the present invention is a sensor element including the resin film (electronic element formation layer) A formed of the resin composition of the present. In one or plurality of embodiments of this discloser, the sensor element of the present invention is a sensor element formed on the resin film A on the base member 500. In one or plurality of embodiments of this discloser, the sensor element of the present invention is a sensor element that can be peeled off from the base member 500.

Examples of the sensor element of the present invention include an optical sensor element for capturing an image, an electromagnetic sensor element for sensing an electromagnetic wave, a radiation sensor element for sensing radiation such as X-rays, a magnetic sensor element for sensing a magnetic field, a capacitive sensor element for sensing a change of capacitance charge, a pressure sensor element for sensing a change of pressure, a touch sensor element and a piezoelectric sensor element.

Examples of the input device using the sensor element of the present invention include a radiation (X-rays) imaging device using the radiation (X-rays) sensor element, a visible-light imaging device using the optical sensor element, a magnetic sensing device using the magnetic sensor element, a touch panel using the touch sensor element or the pressure sensor element, a finger authenticating device using the optical sensor element and a light emitting device using the piezoelectric sensor. The input device using the sensor element of the present invention may further have a function of an output device such as a displaying function and the like.

Hereinafter, an optical sensor element including a photodiode will be described as one example of the sensor element of the present invention.

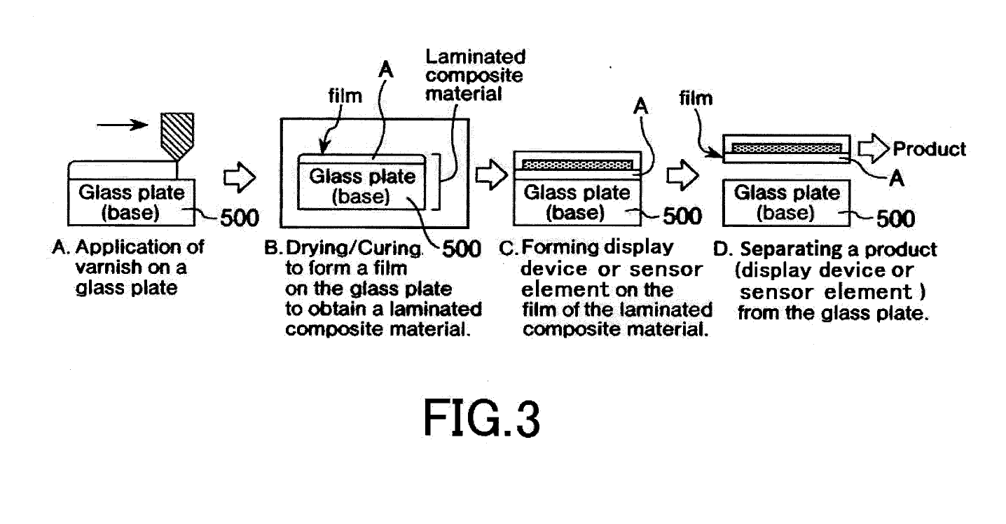

A sensor element 10 shown in FIG. 3 includes the resin film (electronic element formation layer) A formed of the resin composition of the present invention and a plurality of pixel circuits 11 provided on the resin film A.

In this sensor element 10, each of the pixel circuits 11 includes a photodiode (photoelectric conversion element) 11A and a thin-film transistor (TFT) 11B serving as a driver element for the photodiode 11A. By sensing light passing through the resin film A with each of the photodiodes 11A, the sensor element 10 can serve as an optical sensor element.

On the resin film A, a gate insulating film 21 is provided. The gate insulating film 21 is constituted of a single layer film including any one of a silicon oxide (SiO₂) film, a silicon oxynitride (SiON) film and a silicon nitride (SiN) film; or a laminated film including two of more of these films. On the gate insulating film 21, a first interlayer insulating film 12A is provided. The first interlayer insulating film 12 A is constituted of a silicon oxide film, a silicon nitride film or the like. This first interlayer insulating film 12A can also serve as a protective film (passivation film) to cover the top of the thin-film transistor 11B described below.

The photodiode 11A is formed on a selective region of the resin film A through the gate insulating film 21 and the first interlayer insulating film 12A. The photodiode 11A includes a lower electrode 24 formed on the first interlayer insulating film 12A, a n-type semiconductor layer 25N, an i-type semiconductor layer 251, a p-type semiconductor layer 25P, an upper electrode 26 and a wiring layer 27. The lower electrode 24, the n-type semiconductor layer 25N, the i-type semiconductor layer 251, the p-type semiconductor layer 25P, the upper electrode 26 and the wiring layer 27 are laminated from the side of the first interlayer insulating film 12A in this order.

The upper electrode 26 serves as an electrode for supplying, for example, a reference potential (bias potential) to a photoelectric conversion layer during a photoelectric conversion. The photoelectric conversion layer is constituted of the n-type semiconductor layer 25N, the i-type semiconductor layer 251 and the p-type semiconductor layer 25P. The upper electrode 26 is connected to the wiring layer 27 serving as a power supply wiring for supplying the reference potential. This upper electrode 26 is constituted of a transparent conductive film of ITO (indium tin oxide) or the like.

The thin-film transistor 11B is constituted of, for example, a field effect transistor (FET). The thin-film transistor 11B includes a gate electrode 20, a gate insulating film 21, a semiconductor film 22, a source electrode 23S and a drain electrode 23D.

The gate electrode 20 is formed of titanium (Ti), Al, Mo, tungsten (W), chromium (Cr) or the like and formed on the resin film A. The gate insulating film 21 is formed on the gate electrode 20. The semiconductor layer 22 has a channel region and is formed on the gate insulating film 21. The source electrode 23S and the drain electrode 23D are formed on the semiconductor film 22. In this embodiment, the drain electrode 23D is connected to the lower electrode 24 of the photodiode and the source electrode 23S is connected to a relay electrode 28 of the sensor element 10.

Further, in the sensor element 10 of this embodiment, a second interlayer insulating film 12B, a first flattened film 13A, a protective film 14 and a second flattened film 13B are laminated on the photodiode 11A and the thin-film transistor 11B in this order. Further, an opening 3 is formed on the first flattened film 13A so as to correspond to the vicinity of the selective region on which the photodiode 11A is formed.

In the sensor element 10 having such a configuration, the light transmitting from outside into the sensor element 10 passes through the resin film A and reaches to the photodiodes 11A. As a result, it is possible to sensor the light transmitting from outside into the sensor element 10.

(Method of Manufacturing Organic EL Display Device 1 or Sensor Element 10)

The organic EL display device 1 having the configuration as described above or the sensor element 10 having the configuration as described above is manufactured by, for example, using the resin composition of the present invention as follows. That is, the organic EL display device 1 or the sensor element 10 can be manufactured by using the method of manufacturing the electronic device of the present invention.

FIG. 3 is a vertical sectional view to illustrate the method of manufacturing the organic electroluminescence display device shown in FIG. 1 or the sensor element shown in FIG. 2 (method of manufacturing the electronic device of the present invention). In the following description, the upper side in FIG. 3 will be referred to as “upper”, and the lower side in FIG. 3 will be referred to as “lower”.

First, description will be made on the method of manufacturing the organic electroluminescence display device 1 shown in FIG. 1.

[1] First, the substrate (substrate of the present invention) is prepared. The substrate (substrate of the present invention) includes a plate-like base member 500 having a first surface and a second surface opposite to the first surface; and the resin film (electronic element formation layer) A. In this step, the resin film A is provided at a side of the first surface of the base member 500.

[1-A] First, the base member 500 having the first surface and the second surface, and having light transparency is prepared.

For example, glass, a metal, silicone, a resin or the like is used as a constituent material for the base member 500. These materials may be used alone or in combination of two or more as appropriate.

[1-B] Next, the resin film A is formed on the first surface (one surface) of the base member 500. As a result, the substrate including the base member 500 and the resin film A (laminated composite material in FIG. 3) is obtained.

The resin composition of the present invention is used to form the resin film A. The resin composition of the present invention contains an aromatic polyamide, an aromatic multifunctional compound having two or more functional groups including a carboxyl group or an amino group, and a solvent dissolving the aromatic polyamide. By using such a resin composition, it is possible to form the resin film (electronic element formation layer) A containing a reactant obtained by reacting the aromatic polyamide with the aromatic multifunctional compound having the two or more functional groups including the carboxyl group or the amino group.

Examples of the method of forming the resin film A include a method in which the resin composition (varnish) is supplied (cast) on the first surface of the base member 500 by using a die coat method as shown in FIG. 3(A), and thereafter the resin composition is dried and heated (referred to FIG. 3(B)).

In this regard, it is to be noted that a method of supplying the resin composition on the first surface of the base member 500 is not limited to the die coat method. Various kinds of liquid-phase film formation methods such as an ink jet method, a spin coat method, a bar coat method, a roll coat method, a wire bar coat method and a dip coat method can be used as such a method.

Further, as described above, the resin composition of the present invention contains the aromatic polyamide, the aromatic multifunctional compound having the two or more functional groups including the carboxyl group or the amino group, and the solvent dissolving the aromatic polyamide. By using such a resin composition, it is possible to form the resin film A containing the reactant obtained by reacting the aromatic polyamide with the aromatic multifunctional compound having the two or more functional groups including the carboxyl group or the amino group. This resin composition of the present invention will be described later.

[2] Next, the thin-film transistors B are formed on the resin film A provided in the obtained substrate so as to correspond to pixels to be formed. Thereafter, the planarizing layer 301 is formed on the resin film A so as to cover each thin-film transistor B.

[2-A] First, each thin-film transistor B is formed on the resin film A.

[2-Aa] First, a conductive film is formed on the resin film A. Thereafter, the gate electrode 200 is formed by carrying out a patterning treatment to the conductive film.

The formation of the conductive film onto the resin film A can be performed by supplying a metal material such as aluminum, tantalum, molybdenum, titanium and tungsten onto the resin film A with a sputter method and the like. Alternatively, it can be performed by using a wet plating method such as an electrolytic plating method, an immersion plating method and a non-electrolytic plating method or a sol-gel method with a liquid material in which a metal-based compound containing the above metal material is dissolved or dispersed into a solvent or dispersion medium.

[2-Ab] Next, the gate insulating layer 201 is formed on the resin film A so as to cover the gate electrode 200.

This gate insulating layer 201 is formed with a plasma CVD method using, for example, TEOS (tetraethoxysilane), oxygen gas, nitrogen gas and the like as raw material gas (source gas). By using such a plasma CVD method, it is possible to form the gate insulating layer 201 constituted of a silicon oxide or a silicon nitride which is a main material of the gate insulating layer 201.

[2-Ac] Next, the conductive film is again formed on the gate insulating layer 201. Thereafter, the source electrode 202 and the drain electrode 204 are formed by carrying out the patterning treatment to the conductive film on the gate insulating layer 201.

The formation of the conductive film on the gate insulating layer 201 can be performed by using the same method as that described in the step [2-Aa].

[2-Ad] Next, the semiconductor layer 203 is formed in the channel region located between the source electrode 202 and the drain electrode 204.

This semiconductor layer 203 can be formed by a sputtering method under atmosphere containing oxygen (and nitrogen) using a metal target containing the metalloid element and/or the metal element included in the oxide semiconductor material described above.

[2-B] Next, the planarizing layer 301 is formed on the resin film A so as to cover the thin-film transistor B. Further, the conductive part 300 is formed to electrically connect the anode 302 and the drain electrode 204.

[2-Ba] First, the planarizing layer 301 is formed so as to cover the resin film A and the thin-film transistor B formed on the resin film A.

[2-Bb] Next, a contact hole is formed, and then the conduct part 300 is formed in the contact hole.

[3] Next, the light emitting elements (electron element) C are formed on each planarizing layer 301 so as to correspond to each thin-film transistor B.

[3-A] First, the anode (individual electrode) 302 is formed on the planarizing layer 301 so as to correspond to each conductive part 300.

[3-B] Next, the hole transport layer 303 is formed so as to cover the anode 302.

[3-C] Next, the emission layer 304 is formed so as to cover the hole transport layer 303.

[3-D] Next, the electron transport layer 305 is formed so as to cover the emission layer 304.

[3-E] Next, the cathode 306 is formed so as to cover the electron transport layer 305.

In this regard, each layer formed in the steps [3-A] to [3-E] can be formed by using a gas-phase film formation method such as a sputter method, a vacuum deposition method and a CVD method or a liquid-phase film formation method such as an ink jet method, a spin coat method and a casting method. In the case where the liquid-phase film formation method is used, the formation of each layer can be performed by preparing a liquid material in which a constituent material for each layer is dissolved or dispersed into a solvent or dispersion medium, supplying this liquid material onto a layer, on which each layer is to be formed, by using the above liquid-phase film formation method, and then drying it.

[4] Next, the sealing substrate 400 is prepared. Then, the light emitting elements C are sealed with the sealing substrate 400 by covering the cathode 306 of each light emitting device C with the sealing substrate (covering layer) 400. Namely the sealing substrate 400 is formed so as to cover each light emitting element C.

In this regard, the sealing with the sealing substrate 400 as described above can be performed by interposing an adhesive between the cathode 306 and the sealing substrate 400 and then drying the adhesive.

By carrying out the steps [1] to [4] as described above, the organic EL display device 1 including the resin film A, thin-film transistors B, the light emitting elements C and the sealing substrate 400 is formed on the base member 500 (referred to FIG. 3(C)).

[5] Next, the resin film A (electronic element formation layer) is irradiated with light from a side of the base member 500.

By doing so, the resin film A is peeled off from the first surface of the base member 500 in an interface between the base member 500 and the resin film A.

As a result, the organic EL display device (electronic device) 1 is separated from the base member 500 (referred to FIG. 3(D)).

The light to be irradiated to the resin film A is not particularly limited to a specific kind as long as the resin film A can be peeled off from the first surface of the base member 500 in the interface between the base member 500 and the resin film A by irradiating the resin film A with the light. The light is preferably laser light. By using the laser light, it is possible to reliably peel off the resin film A from the base member 500 in the interface between the base member 500 and the resin film A.

Further, examples of the laser light include an excimer laser of a pulse oscillator type or a continuous emission type, a carbon dioxide laser, a YAG laser and a YVO₄ laser.

By carrying out the steps [1] to [5] as described above, it is possible to obtain the organic electroluminescence display device 1 peeled off from the base member 500.

Next, description will be made on the method of manufacturing the sensor element shown in FIG. 3.

[1] First, in the same manner as the method of manufacturing the organic electroluminescence display device shown in FIG. 1, the substrate (substrate of the present invention) including the base member 500 and the resin film (electronic element formation layer) A formed on the base member 500 is prepared. Since a step for forming the resin film A on the base member 500 is identical to that of the method of manufacturing the organic electroluminescence display device 1 described above, description to the step for forming the resin film A on the base member 500 is omitted here (referred to FIGS. 3(A) and 3(B)).

[2] Next, the sensor element 10 described above is formed on the resin film A provided in the obtained substrate. A method for forming the sensor element 10 on the resin film A is not particularly limited to a specific method. The formation of the sensor element 10 on the resin film A can be carried out with a known suitable method appropriately selected or modified for manufacturing a desired sensor element.

By carrying out the steps [1] to [2] as described above, the sensor element 10 including the resin film A, the pixel circuits 11 is formed on the base member 500 (referred to FIG. 3(C)). In the same manner as the method of manufacturing the organic EL display device 1, the liquid material is also supplied on the resin film A for forming each element and each film (layer) in the step [2].

[3] Next, the resin film (electronic element formation layer) A is irradiated with the light from the side of the base member 500 to peel off the sensor element (electronic device) 10 from the base member 500 (referred to FIG. 4(D)). Since a step for peeling off the sensor element from the base member 500 is identical to the above-mentioned step for peeling off the organic electroluminescence display device 1 from the base member 500, description to the step for peeling off the sensor element 10 from the base member 500 is omitted here.

By carrying out the steps [1] to [3] as described above, it is possible to obtain the sensor element 10 peeled off from the base member 500.

In this way, the organic EL display device 1 separated from the base member 500 is manufactured. According to the manufacture of the organic EL display device 1, each element provided therein (gate electrode and light emitting element) may be formed by using the liquid material in the steps [2-Aa] and [3-A] to [3-E]. In the case where the resin film A has poor solvent resistance with respect to a solvent contained in the liquid material, by forming each element with the liquid material, at least a part of the resin film A is exposed to the liquid material. Thus, there is a risk where a constituent material of the resin film A is altered or deteriorated. Due to the alteration or the deterioration of the resin film A, a problem in that adverse effects are given to a display property of the organic EL display device 1 occurs.

As described above, the liquid material is also supplied onto the resin film A for forming each element and each film (layer) in the method for manufacturing the sensor element 10. Thus, in the case where the resin film A has poor solvent resistance with respect to the solvent contained in the liquid material, by forming each element and each film (layer) with the liquid material, at least a part of the resin film A is exposed to the liquid material. Thus, there is a risk where the constituent material of the resin film A is altered or deteriorated. Due to the alteration or the deterioration of the resin film A, a problem in that adverse effects are given to a detecting property of the sensor element 10 occurs.

For the purpose of solving such a problem, in the present invention, the resin film A is constituted from a layer containing the reactant obtained by reacting the aromatic polyamide with the aromatic multifunctional compound having the two or more functional groups including the carboxyl group or the amino group. Since the resin film A having such a configuration exhibits excellent solvent resistance, it is possible to reliably prevent or suppress the resin film A from being altered or deteriorated even if the resin film A is exposed to the solvent (or dispersion medium) contained in the liquid material in the steps [2-Aa] and [3-A] to [3-E]. Therefore, it is possible to reliably prevent the adverse effects from being given to the display property of the organic EL display device 1 or the detecting property of the sensor element 10 due to the exposure of the resin film A to such a liquid material.

As described above, the resin film A having the configuration as described above can be formed by using the resin composition of the present invention which contains the aromatic polyamide, the aromatic multifunctional compound having the two or more functional groups including the carboxyl group or the amino group, and the solvent dissolving the aromatic polyamide. Hereinafter, detailed description will be made on constituent materials for the resin composition of the present invention.

[Aromatic Polyamide]

The aromatic polyamide is used as one main material of the resin composition. By containing the aromatic polyamide in the resin composition, it is possible to form the resin film (electronic element formation layer) A from the reactant obtained by reacting the aromatic polyamide with the aromatic multifunctional compound having the two or more functional groups including the carboxyl group or the amino group. The reactant is a major component of the resin film A.

Furthermore, by containing the aromatic polyamide in the resin composition, it is also possible to efficiently perform the peeling-off of the resin film A from the base member 500 in the interface between the base member 500 and the resin film A due to the irradiation of the light to the resin film A.

The aromatic polyamide is not particularly limited to specific kind as long as it can set a total light transmittance of the resin film A in the wavelength of 355 nm to be 10% or less.

It is preferred that the aromatic polyamide is a wholly aromatic polyamide. By using the resin composition containing the wholly aromatic polyamide, it is possible to reliably set the total light transmittance of the formed resin film A to fall within the above range. In this regard, it is to be noted that the wholly aromatic polyamide refers to that all of amide bonds included in a main chain of the aromatic polyamide are bonded to each other through the aromatic group (aromatic ring) without bonding to each other through a chain or cyclic aliphatic group.

In view of the foregoing, it is preferred that the aromatic polyamide has a repeating unit represented by the following general formula (I):

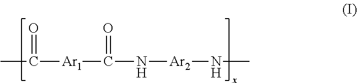

where x is an integral number of 1 or more, Ar₁ is represented by the following general formula (II), (III) or (IV):

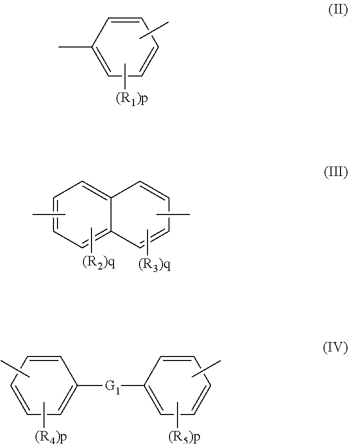

(where p=4; q=3; each of R₁, R₂, R₃, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), and Are is represented by the following general formula (V) or (VI):

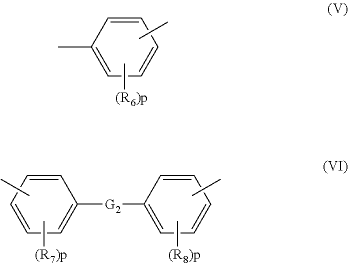

(where p=4; each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₂ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, a SO₂ group, a Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

Further, it is preferred that the resin composition contain the aromatic polyamide in order to set the total light transmittance of the resin film A in the wavelength of 355 nm at a desired value. In particular, by containing the aromatic polyamide in the resin composition, the total light transmittance of the resin film A in the wavelength of 355 nm is preferably set to be 10% or less, more preferably set to be 5% or less, further more preferably set to be 2% or less, and even more preferably set to be 1% or less. By setting the total light transmittance of the resin film A in the wavelength of 355 nm to fall within the above range, it is possible to reliably suppress or prevent light (in particular, light having a short wavelength) irradiated from the side of the first surface of the base member 500 into the resin film A from transmitting through the resin film A.

In the case where the resin film A has the light transparency in a short wavelength, when light having the short wavelength is irradiated from the side of the first surface of the base member 500 to the resin film A in the step of peeling off the resin film A, the semiconductor layer 203 provided in each thin-film transistor B is irradiated with the light including the light having the short wavelength. The exposure of the semiconductor layer 203 with respect to the light having the short wavelength causes alteration or deterioration of the oxide semiconductor material included in the semiconductor layer 203. As a result, adverse effects are given to a switching property of the organic EL display device 1.

In the same manner, the light irradiated from the side of the first surface of the base member 500 to the resin film A transmits through the resin film A, and then reaches the photodiodes 11A and the thin-film transistors 11B provided in the sensor element 10. At this time, if the irradiated light contains the light having the short wavelength, oxide semiconductor materials included in the semiconductor layers 25N, 25I, 25P provided in each photodiode 11A and an oxide semiconductor material included in the semiconductor film 22 in each thin-film transistor 11B are altered or deteriorated due to the exposure to the light having the short wavelength. As a result, a problem in that adverse effects are given to switching property of the sensor element 10 occurs.

On the other hand, in the present invention, it is possible to appropriately prevent or suppress the light having the short wavelength from transmitting through the resin film A. This makes it possible to reliably prevent the adverse effects from being given to the switching property of the organic EL display device 1 and the switching property of the sensor element 10.

Further, it is preferred that the aromatic polyamide, which can set the total light transmittance of the resin film A to fall within the above range, contains a naphthalene structure as a main chemical structure thereof. Specifically, the aromatic polyamide containing the repeating unit represented by the above general formula (I) in which Ar₁ is represented by the above general formula (III) is preferable. By using the resin composition containing such an aromatic polyamide, it is possible to reliably set the total light transmittance of the formed resin film A to fall within the above range.

In one or plurality of embodiments of this disclosure, the general formulas (I) and (II) are selected so that the aromatic polyamide is soluble in a polar solvent or a mixed solvent containing one or more polar solvents. In one or plurality of embodiments of this disclosure, x varies in the range of 90.0 to 99.99 mol % of the general formula (I), and y varies in the range of 10.0 to 0.01 mol % of the general formula (II). In one or plurality of embodiments of this disclosure, x varies in the range of 90.1 to 99.9 mol % of the general formula (I), and y varies in the range of 9.9 to 0.1 mol % of the general formula (II). In one or plurality of embodiments of this disclosure, x varies in the range of 90.0 to 99.0 mol % of the general formula (I), and y varies in the range of 10.0 to 1.0 mol % of the general formula (II). In one or plurality of embodiments of this disclosure, x varies in the range of 92.0 to 98.0 mol % of the general formula (I), and y varies in the range of 8.0 to 2.0 mol % of the general formula (II). In one or plurality of embodiments of this disclosure, the aromatic polyamide contains multiple repeat units represented with the general formulas (I) and (II) where Ar₁, Ar₂, and Ar₃ may be the same as or different from each other.

Further, a number average molecular weight (Mn) of the aromatic polyamide is preferably 6.0×10⁴ or more, more preferably 6.5×10⁴ or more, more preferably 7.0×10⁴ or more, further more preferably 7.5×10⁴ or more, and even more preferably 8.0×10⁴ or more. Further, the number average molecular weight of the aromatic polyamide is preferably 1.0×10⁶ or less, more preferably 8.0×10⁵ or less, further more preferably 6.0×10⁵ or less, and even more preferably 4.0×10⁵ or less. By using the aromatic polyamide satisfying the above condition, it is possible for the resin film A to reliably provide a function as a foundation layer in the organic EL display device 1 or the sensor element 10. Further, it is possible to reliably allow the resin film A to have excellent solvent resistance.

In the present specification, the number average molecular weight (Mn) and a weight average molecular weight (Mw) of the aromatic polyamide are measured with a Gel Permeation Chromatography. Specifically, they are measured by using the method in the following Examples.

Further, molecular weight distribution of the aromatic polyamide (=Mw/Mn) is preferably 5.0 or less, more preferably 4.0 or less, more preferably 3.0 or less, further more preferably 2.8 or less, further more preferably 2.6 or less, and even more preferably 2.4 or less. Further, the molecular weight distribution of the aromatic polyamide is preferably 2.0 or more. By using the aromatic polyamide satisfying the above condition, it is possible for the resin film A to reliably provide the function as the foundation layer in the organic EL display device 1 or the sensor element 10. Further, it is possible to reliably allow the resin film A to have excellent solvent resistance.

It is preferred that the aromatic polyamide is obtained through a step of re-precipitating it after the aromatic polyamide is synthesized. By using the aromatic polyamide obtained through the step of re-precipitation, it is possible for the resin film A to reliably provide the function as the foundation layer in the organic EL display device 1 or the sensor element 10. Further, it is possible to reliably allow the resin film A to have excellent solvent resistance.

In one or plurality of embodiments of this disclosure, one or both of a terminal COOH group and a terminal NH₂ group of the aromatic polyamide are end-capped. The end-capping of the terminals is preferable from the point of view of enhancement of heat resistance property of the polyamide film (namely, resin film A). The terminals of the aromatic polyamide can be end-capped by either being reacted with benzoyl chloride in the case where each terminal thereof is —NH₂ or by being reacted with aniline in the case where each terminal thereof is —COOH. However, the method of end-capping is not limited to this method.

[Aromatic Multifunctional Compound]

The aromatic multifunctional compound has the two or more functional groups including the carboxyl group or the amino group. The aromatic multifunctional compound is used as another main material of the resin composition. By containing the aromatic multifunctional compound in the resin composition, it is possible to form the resin film (electronic element formation layer) A from the reactant obtained by reacting the aromatic polyamide with the aromatic multifunctional compound having the two or more functional groups including the carboxyl group or the amino group. As mentioned above, the reactant is the major component of the resin film A.

Furthermore, by containing the aromatic multifunctional compound in the resin composition, it is possible to improve the solvent resistance of the resin film A which is the layer (film) constituted from the reactant obtained by reacting the aromatic polyamide with the aromatic multifunctional compound having the two or more functional groups including the carboxyl group or the amino group as the major component thereof.

The aromatic multifunctional compound preferably contains the carboxyl group as each functional group. By using the aromatic multifunctional compound containing the carboxyl group, it is possible to reliably progress the reaction of the aromatic polyamide with the aromatic multifunctional compound. This makes it possible to more reliably improve the solvent resistance of the formed resin film A.

Further, the aromatic multifunctional compound preferably contains one aromatic ring or two or more aromatic rings. By using the aromatic multifunctional compound containing the one aromatic ring or two or more aromatic rings, it is possible to more reliably improve the solvent resistance of the formed resin film A. In the case where the aromatic multifunctional compound contains two (multi) aromatic rings, the aromatic rings may be either fused multicyclic ring systems or linked multicyclic ring systems.

Considering these points, a compound represented by the following general formula (A), (B) or (C) is preferably used as the aromatic multifunctional compound.

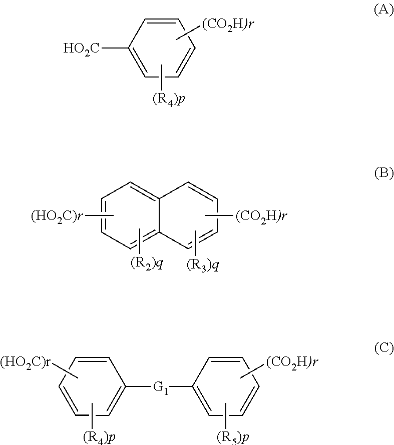

where r=1 or 2, p=3 or 4, q=2 or 3, each of R₁, R₂, R₃, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).

Among them, the compound represented by the above general formula (A) is preferably used. More particular, trimesic acid is preferably used. By using the resin composition containing such a compound as the aromatic multifunctional compound, it is possible to more reliably improve the solvent resistance of the formed resin film A.

Furthermore, an amount of the aromatic multifunctional compound contained in the resin composition is preferably in the range of 1 to 10 wt %, and more preferably in the range of 3 to 7 wt % with respect to an amount of the aromatic polyamide contained therein. By setting the amount of the aromatic multifunctional compound in the resin composition to fall within the above range, it is possible to more reliably improve the solvent resistance of the resin film A.

[Inorganic Filler]

It is preferred that the resin composition contains an inorganic filler in addition to the aromatic polyamide. By using the resin composition containing the inorganic filler, it is possible to reduce a coefficient of thermal expansion (CTE) of the resin film A and to reliably improve the solvent resistance of the resin film A.

This inorganic filler is not particularly limited to a specific kind, but is preferably constituted of a fiber or is preferably formed into a particle shape.

Further, a constituent material for the inorganic filler is not particularly limited to a specific material as long as it is an inorganic material. Examples of such a constituent material for the inorganic filler include a metal oxide such as silica, alumina and a titanium oxide; a mineral such as mica; glass; and a mixture of them. These materials may be used singly or in combination of two or more of them. In this regard, examples of a kind of glass include E glass, C glass, A glass, S glass, D glass, NE glass, T glass, low permittivity glass and high permittivity glass.

In the case where the inorganic filler is constituted of the fiber, an average fiber diameter of the fiber is preferably in the range of 1 to 1000 nm. By using the resin composition containing the inorganic filler having the above average fiber diameter, it is possible for the resin film A to reliably provide the function as the foundation layer in the organic EL display device 1 or the sensor element 10. Further, it is possible to reliably improve the solvent resistance of the resin film A.

Here, the fiber may be formed of single fibers. The single fibers included therein are arranged without paralleling with each other and to be sufficiently spaced apart from each other so that a liquid precursor of a matrix resin enters among the single fibers. In this case, the average fiber diameter corresponds to an average diameter of the single fibers. Further, the fiber may constitute one line of thread in which a plurality of single fibers are bundled. In this case, the average fiber diameter is defined as an average value of a diameter of the one line of thread. Specifically, the average fiber diameter is measured by the method in the Examples. Further, from the point of view of improving the transparency of the film, the average fiber diameter of the fiber is preferably small. Further, a refractive index of the aromatic polyamide included in the resin composition (polyamide solution) and a refractive index of the inorganic filler are preferably close to each other. For example, in the case where a difference of refractive indexes of a material to be used as the fiber and the aromatic polyamide in the wavelength of 589 nm is 0.01 or less, it becomes possible to form a film having high transparency regardless of the fiber diameter. Further, examples of a method of measuring the average fiber diameter include a method of observing the fiber with an electronic microscope.

Further, in the case where the inorganic filler is formed into the particle shape, an average particle size of the particles is preferably in the range of 1 to 1000 nm. By using the resin composition containing the inorganic filler in the form of the particle shape having the above average particle size, it is possible for the resin film A to reliably provide the function as the foundation layer in the organic EL display device 1 or the sensor element 10. Further, it is possible to reliably improve the solvent resistance of the resin film A.

Here, the average particle size of the particles refers to a diameter corresponding to an average projection circle. Specifically, the average particle size of the particles is measured by the method in the Examples.

A shape of each of the particles is not particularly limited to a specific shape. Examples of the shape include a spherical shape, a perfect spherical shape, a rod shape, a plate shape and a combined shape of them. By using the inorganic filler having such a shape, it is possible to reliably improve the solvent resistance of the resin film A.

Further, the average particle size of the particles is preferably small. Further, the refractive index of the aromatic polyamide included in the resin composition (polyamide solution) and the refractive index of the inorganic filler are preferably close to each other. This makes it possible to further improve the transparency of the resin film A. For example, in the case where a difference of refractive indexes of the material to be used as the particles and the aromatic polyamide in the wavelength of 589 nm is 0.01 or less, it becomes possible to form the resin film A having high transparency regardless of the particle size. Further, examples of a method of measuring the average particle size include a method of measuring the average particle size with a particle size analyzer.

A ratio of the inorganic filler in a solid matter contained in the resin composition (polyamide solution) is not particularly limited to a specific value, but is preferably in the range of 1 to 50 volume %, more preferably in the range of 2 to 40 volume %, and even more preferably in the range of 3 to 30 volume %. On the other hand, a ratio of the aromatic polyamide in the solid matter contained in the resin composition (polyamide solution) is not particularly limited to a specific value, but is preferably in the range of 50 to 99 volume %, more preferably in the range of 60 to volume %, and even more preferably in the range of 70 to 97 volume %.

In this regard, it is to be noted that the “solid matter” refers to a component other than the solvent contained in the resin composition in this specification. A volume conversion of the solid matter, a volume conversion of the inorganic filler and/or a volume conversion of the aromatic polyamide can be calculated from each element usage at the time of preparing the polyamide solution. Alternatively, they can be also calculated by removing the solvent from the polyamide solution.

[Other Components]

Furthermore, the resin composition may contain an antioxidant, au ultraviolet absorbing agent, a dye, a pigment, a filler such as another inorganic filler and the like, if needed, in the degrees to which the function of the foundation layer in the organic EL display device 1 or the sensor element 10 is not impaired and the total light transmittance of the resin film A is set to fall within the range described above.

[Amount of Solid Matter]

A ratio of the solid matter contained in the resin composition is preferably 1 volume % or more, more preferably volume % or more, and even more preferably 3 volume % or more. Further, the ratio of the solid matter contained in the resin composition is preferably 40 volume % or less, more preferably 30 volume % or less, and even more preferably 20 volume % or less. By setting the ratio of the solid matter contained in the resin composition to fall within the above range, it is possible for the resin film A to reliably provide the function as the foundation layer in the organic EL display device 1 or the sensor element 10. Further, it is possible to reliably set the total light transmittance of the resin film A to fall within the range described above.

[Solvent]

One to be able to solve the aromatic polyamide is used as the solvent, which is used to prepare a varnish (liquid material) containing the resin composition.

The solvent used for preparing the liquid material is preferably a polar solvent. By using the polar solvent for preparing the liquid material, it is possible to reliably dissolve the aromatic polyamide into the polar solvent. Further, in the case where such a polar solvent is used for producing the aromatic polyamide as described below, it is possible to smoothly progress a reaction of the aromatic diamine with an aromatic diacid dichloride.

Furthermore, the solvent may be either an organic solvent or an inorganic solvent, but is preferably the organic solvent. By using the organic solvent, it is possible to reliably dissolve the aromatic polyamide into the organic solvent. Further, in the case where such an organic solvent is used for producing the aromatic polyamide as described below, it is possible to easily remove by-products such as free hydrochloric acid which would be generated during the production of the aromatic polyamide.

In one or plurality of embodiments of this disclosure, in terms of enhancement of solubility of the aromatic polyamide to the solvent, the solvent is preferably a polar solvent or a mixed solvent containing one or more polar solvents. In one or plurality of embodiments of this disclosure, in terms of enhancement of solubility of the aromatic polyamide to the solvent and enhancement of the adhesion between the resin film A and the base member 500, the solvent is preferably cresol; N,N-dimethyl acetamide (DMAc); N-methyl-2-pyrrolidinone (NMP); dimethyl sulfoxide (DMSO); 1,3-dimethyl-imidazolidinone (DMI); N,N-dimethyl formamide (DMF); butyl cellosolve (BCS); γ-butyrolactone (GBL) or a mixed solvent containing at least one of cresol, N,N-dimethyl acetamide (DMAc), N-methyl-2-pyrrolidinone (NMP), dimethyl sulfoxide (DMSO), 1,3-dimethyl-imidazolidinone (DMI), N,N-dimethyl formamide (DMF), butyl cellosolve (BCS) and γ-butyrolactone (GBL); a combination thereof or a mixed solvent containing at least one of the polar solvent thereof.

Among these polar solvents, the N,N-dimethyl acetamide (DMAc) is especially preferably used. By using the N,N-dimethyl acetamide (DMAc) as the solvent, it is possible to more markedly exhibit the above effects.

As described above, the resin film A is obtained by supplying (casting) the resin composition containing the above components onto the first surface of the base member 500, and then drying and heating it. For example, conditions in each step are set as follows.

In the step of supplying (casting) the resin composition onto the first surface of the base member 500, a temperature of the resin composition is preferably set to be lower than 220° C., and more preferably set to be lower than 180° C. By setting the temperature of the resin composition in this step to fall within the above range, it is possible to supply (cast) the resin composition onto the first surface of the base member 500 so that a thickness of the resin film A become uniform, and to reliably prevent or suppress the reaction of the aromatic polyamide with the aromatic multifunctional compound from unintendedly progressing.

In the step of drying and heating the resin composition on the first surface of the base member 500, a temperature of the resin composition is preferably set to be near a glass transition temperature (Tg) of the aromatic polyamide. More specifically, the temperature of the resin composition is preferably set to be in the range of Tg±10° C., and more preferably set to be in the range of Tg±5° C. By setting the temperature of the resin composition in this step to fall within the above range, it is possible to react the aromatic polyamide with the aromatic multifunctional compound, to thereby produce the reactant, which is obtained by reacting the aromatic polyamide with the aromatic multifunctional compound, in the resin film A. As a result, the resin film A can exhibit excellent solvent resistance with respect to both of the inorganic solvent and the organic solvent.

Regarding general amides, it is well-known that the general amides undergo transamidation reactions. Such reactions would not be expected to occur rapidly (radically), for example, between a carboxylic acid and a main chain of a polyamide. Since the transamidation reaction between the carboxylic acid and the main chain of the polyamide is not radical, in the conventional art, the carboxylic acid has not been used as a crosslinking agent in the thermal cure of the polyamide. Especially, an aromatic polyamide has a very high Tg and is insoluble in general inorganic solvents. For the reasons stated above, the thermal crosslinking of the aromatic polyamide has not been subject to study.

However, in the present invention, by using the aromatic multifunctional compound having the carboxyl group(s) as the functional group, it is possible to cross-link even the aromatic polyamide by heating the aromatic polyamide for a relatively short period of time, to thereby impart high solvent resistance to the resin film A. This is also apparent from the fact that thermal degradation and color development of the resin film A do not occur.

In this regard, it is to be noted that a time (duration) of drying and heating the resin composition is preferably 1 minute or longer, and more preferably in the range of 1 to 60 minutes.

Further, the drying and heating of the resin composition is preferably carried out under reduced pressure or inert atmosphere.

As described above, the resin film A can exhibit high solvent resistance with respect to various solvents, especially preferably with respect to a polar solvent. Examples of such a polar solvent include cresol; N,N-dimethyl acetamide (DMAc); N-methyl-2-pyrrolidinone (NMP); dimethyl sulfoxide (DMSO); 1,3-dimethyl-imidazolidinone (DMI); N,N-dimethyl formamide (DMF); butyl cellosolve (BCS); γ-butyrolactone (GBL) or a mixed solvent containing at least one of cresol, N,N-dimethyl acetamide (DMAc), N-methyl-2-pyrrolidinone (NMP), dimethyl sulfoxide (DMSO), 1,3-dimethyl-imidazolidinone (DMI), N,N-dimethyl formamide (DMF), butyl cellosolve (BCS) and γ-butyrolactone (GBL); a combination thereof; and a mixed solvent containing at least one of the polar solvent thereof.

[Method of Manufacturing Resin Composition]

The resin composition as described above can be manufactured by, for example, using a manufacturing method including the following steps.

However, the resin composition of the present invention is not limited to a resin composition manufactured by using the following manufacturing method.

A method of manufacturing a resin composition according to this embodiment includes:

(a) mixing one or more aromatic diamines with a solvent to obtain a mixture;

(b) reacting an aromatic diacid dichloride with the aromatic diamines by adding the aromatic diacid dichloride into the mixture to produce a solution containing the aromatic polyamide and hydrochloric acid;

(c) removing the hydrochloric acid from the solution; and

(d) adding the aromatic multifunctional compound having the two or more functional groups including the carboxyl group or the amino group into the solution to manufacture the resin composition.

Hereinbelow, each step will be described one after another.

Step (a) First, the one or more aromatic diamines are mixed with (dissolved into) the solvent to obtain the mixture.

In one or more embodiments of the method for manufacturing the resin composition of this disclosure, examples of the aromatic diamine include compounds represented by the following general formulas (D) and (E)

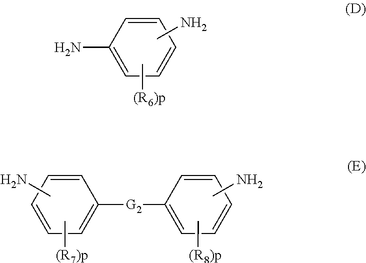

where p=4, each of R₆, R₇ and R₈ is selected from the group consisting of a hydrogen atom, a halogen atom (a fluorine atom, a chlorine atom, a bromine atom, and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and combinations thereof, and G₂ is selected from the group consisting of a covalent bond, a CH₂ group, a C(CH₃)₂ group, a C(CF₃)₂ group, a C(CX₃)₂ group (wherein X represents a halogen atom.), a CO group, an oxygen atom, a sulfur atom, an SO₂ group, an Si (CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).

Specifically, examples of the aromatic diamine as described above include the following compounds. These compounds may be used alone or in combination of two or more of them.

### 4,4′-diamino-2,2′-bistrifluoromethyl benzidine (PFMB)

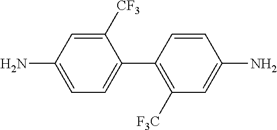 [SMILES: Nc1ccc(-c2ccc(N)cc2C(F)(F)F)c(C(F)(F)F)c1]

### 4,4′-diamino-2,2′-bistrifluoromethoxyl benzidine (PFMOB)

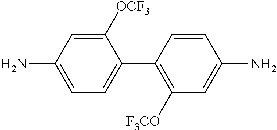 [SMILES: Nc1ccc(-c2ccc(N)cc2OC(F)(F)F)c(OC(F)(F)F)c1]

### 4,4′-diamino-2,2′-bistrifluoromethyl diphenyl ether (GFODA)

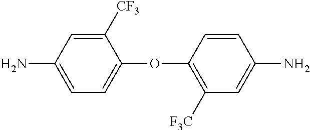 [SMILES: Nc1ccc(Oc2ccc(N)cc2C(F)(F)F)c(C(F)(F)F)c1]

### Bis(4-amino-2-trifluoromethyl phenyloxyl) benzene (6FOQDA)

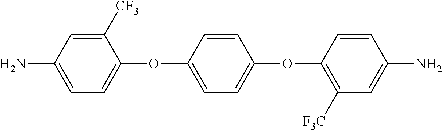 [SMILES: Nc1ccc(Oc2ccc(Oc3ccc(N)cc3C(F)(F)F)cc2)c(C(F)(F)F)c1]

### Bis(4-amino-2-trifluoromethyl phenyloxyl) biphenyl (6FOBDA)

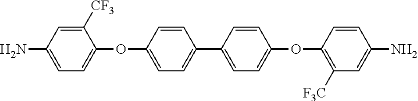 [SMILES: Nc1ccc(Oc2ccc(-c3ccc(Oc4ccc(N)cc4C(F)(F)F)cc3)cc2)c(C(F)(F)F)c1]

### 9,9-bis(4-aminophenyl) fluorine (FDA)

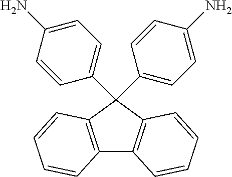 [SMILES: Nc1ccc(C2(c3ccc(N)cc3)c3ccccc3-c3ccccc32)cc1]

### 9,9-bis(3-fluoro-4-aminophenyl) fluorine (FFDA)

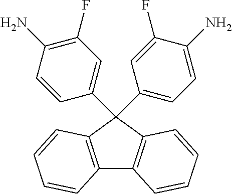 [SMILES: Nc1ccc(C2(c3ccc(N)c(F)c3)c3ccccc3-c3ccccc32)cc1F]

### 3,5-diaminobenzoic acid (DAB)

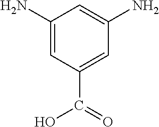 [SMILES: Nc1cc(N)cc(C(=O)O)c1]

### 4,4′-diaminodiphenyl sulfone (DDS)

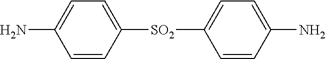 [SMILES: Nc1ccc(S(=O)(=O)c2ccc(N)cc2)cc1]

Regarding the diaminodiphenyl sulfone (DDS), the diaminodiphenyl sulfone may be 4,4′-diaminodiphenyl sulfone as expressed by the above formula, 3,3′-diaminodiphenyl sulfone or 2,2′-diaminodiphenyl sulfone.

Further, the above mentioned solvent, which is contained in the resin composition, can be used as a solvent in this step.

Step (b): Next, the aromatic diacid dichloride is added into the mixture. At this time, the aromatic diacid dichloride is reacted with the aromatic diamines contained in the mixture. As a result, the solution containing the aromatic polyamide and the hydrochloric acid is produced.

In one or more embodiments of the method for manufacturing the resin composition of this disclosure, examples of the aromatic diacid dichloride include compounds represented by the following general formulas (F) to (H):

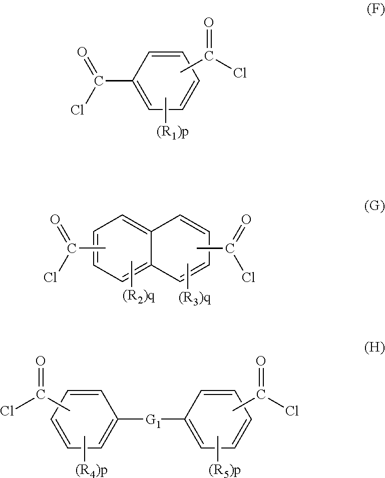

where p=4, q=3, each of R₁, R₂, R₃, R₄ and R₅ is selected from the group consisting of a hydrogen atom, a halogen atom (a fluorine atom, a chlorine atom, a bromine atom, and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and combinations thereof, and G₁ is selected from the group consisting of a covalent bond, a CH₂ group, a C(CH₃)₂ group, a C(CF₃)₂ group, a C(CX₃)₂ group (wherein X represents a halogen atom.), a CO group, an oxygen atom, a sulfur atom, an SO₂ group, an Si (CH₃)₂ group, a 9,9-fluorene group, a substituted 9,9-fluorene group, and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).

Specifically, examples of the aromatic diacid dichloride as described above include the following compounds.

### Terephthaloyl dichloride (TPC)

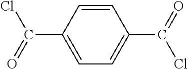 [SMILES: O=C(Cl)c1ccc(C(=O)Cl)cc1]

### Isophthaloyl dichloride (IPC)

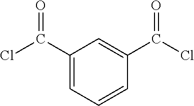 [SMILES: O=C(Cl)c1cccc(C(=O)Cl)c1]

### 2,6-naphthaloyl dichloride (NDC)

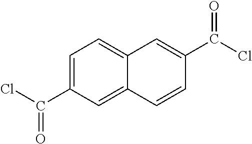 [SMILES: O=C(Cl)c1ccc2cc(C(=O)Cl)ccc2c1]

### 4,4-biphenyldicarbonyl dichloride (BPDC)

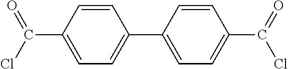 [SMILES: O=C(Cl)c1ccc(-c2ccc(C(=O)Cl)cc2)cc1]

In one or plurality of embodiments of this disclosure, in terms of enhancement of heat resistance property of the resin film A, the method further includes a step of end-capping one or both of the terminal —COOH group and the terminal —NH₂ group of the aromatic polyamide. The terminals of the aromatic polyamide can be end-capped by either being reacted with benzoyl chloride in the case where each terminal thereof is —NH₂ or by being reacted with aniline in the case where each terminal thereof is —COOH. However, the method of end-capping is not limited to this method.

Step (c): Next, the hydrochloric acid which is the by-product is removed from the solution. Namely, the aromatic polyamide is separated from the hydrochloric acid.

Examples of a method of separating the aromatic polyamide from the hydrochloric acid include a method 1) in which a reagent is added into the solution so that a volatile component is produced due to the reaction of the reagent with the hydrochloric acid, to thereby remove the volatile component from the solution, and a method 2) in which a reagent is added into the solution so that a non-volatile component is produced due to the reaction of the reagent with the hydrochloric acid, the aromatic polyamide is isolated from the solution by re-precipitating it, and then the aromatic polyamide re-dissolved into another solvent. According to the above methods 1) and 2), it is possible to reliably trap the hydrochloric acid contained in the solution by the reagent, and thus reliably removing the hydrochloric acid from the solution.

Examples of the reagent to be used in the method 1) include propylene oxide (PYO) and the like.

In one or plurality of embodiments of this disclosure, the reagent (trapping reagent) is added to the solution before or during the step (c). By adding the reagent before or during the step (c), it is possible to reduce a degree of viscosity and generation of condensation in the solution after the step (c), and thereby, improving productivity of the resin composition. These effects become especially remarkable when the reagent is an organic reagent such as propylene oxide.

Examples of the reagent to be used in the method 2) include an inorganic salt. These compounds may be used alone or in combination of two or more of them.

In the method 2), the re-precipitation of the aromatic polyamide can be carried out with a known method. In one or plurality of embodiments of this disclosure, the re-precipitation can be carried out by adding the solution to, for example, methanol, ethanol, isopropyl alcohol or the like.

By removing the hydrochloric acid from the solution according to the above way, it is possible to obtain a resin composition containing no inorganic salts.

Further, in the case of using the method 1), it is unnecessary to carry out a step of isolating the aromatic polyamide (polymer). Thus, in the case of using the method 1), it is possible to simplify the processes and reduce the cost for manufacturing the resin composition.

Step (d): Next, the aromatic multifunctional compound is added into the solution. In this step, it is possible to manufacture the resin composition containing the aromatic polyamide, the aromatic multifunctional compound having the two or more functional groups including the carboxyl group or the amino group, and the solvent dissolving the aromatic polyamide (that is, the resin composition of the present invention is obtained).

In one or more embodiments of the method for manufacturing the resin composition of this disclosure, examples of the aromatic multifunctional compound include compounds represented by the following general formulas (A) to (C):

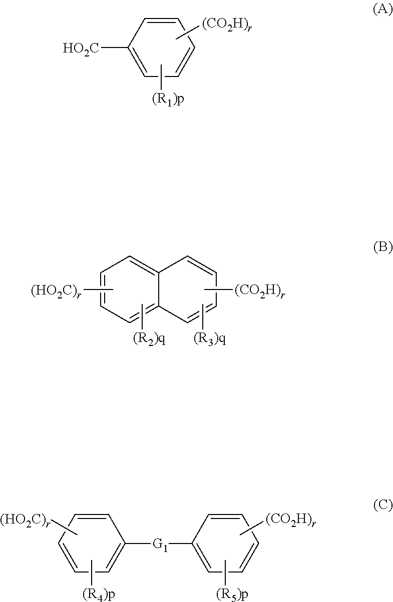

where r=1 or 2, p=3 or 4, q=2 or 3, each of R₁, R₂, R₃, R₄ and R₅ is selected from the group consisting of a hydrogen atom, a halogen atom (a fluorine atom, a chlorine atom, a bromine atom, and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and combinations thereof, and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).

Specifically, examples of the aromatic multifunctional compound as described above include the following compounds.

### Trimesic acid (TA)

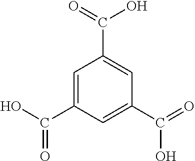 [SMILES: O=C(O)c1cc(C(=O)O)cc(C(=O)O)c1]

### 2,4,6,8-naphthyl tetracarboxylic acid (TTNA)

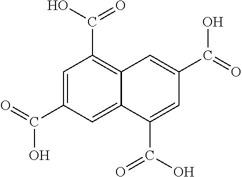 [SMILES: O=C(O)c1cc(C(=O)O)c2cc(C(=O)O)cc(C(=O)O)c2c1]

### 3,3′,5,5′-biphenyl tetracarboxylic acid (BPTA 1)

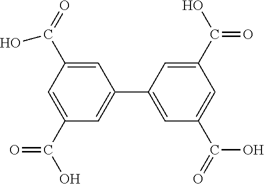 [SMILES: O=C(O)c1cc(C(=O)O)cc(-c2cc(C(=O)O)cc(C(=O)O)c2)c1]

### 2,2′,4,4′-biphenyl tetracarboxylic acid (BPTA 2)

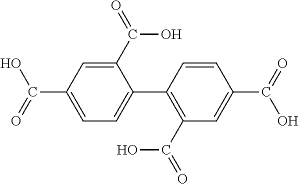 [SMILES: O=C(O)c1ccc(-c2ccc(C(=O)O)cc2C(=O)O)c(C(=O)O)c1]

By taking the steps as described above, the resin composition can be manufactured.

Further, it is preferred that the total light transmittance of the resin film A, which is formed by using the resin composition, in a wavelength of 400 to 750 nm is set to become high. In particular, the total light transmittance of the resin film A in the wavelength of 400 nm is preferably 70% or more, more preferably 75% or more, and even more preferably 90% or more. Further, the total light transmittance of the resin film A in the wavelength of 550 nm is preferably 80% or more, more preferably 85% or more, and even more preferably 95% or more. By setting the total light transmittances of the resin film A to fall within the above ranges, it is possible for light (visible light) having a long wavelength to reliably transmit through the resin film A, to thereby reliably extract the light emitted from the light emitting elements C outside the organic EL display device 1 and reliably introduce the light transmitting from outside into the sensor element 10.

Furthermore, a coefficient of thermal expansion (CTE) of the resin film A is preferably 100.0 ppm/K or less, more preferably 80 ppm/K or less, further more preferably 60 ppm/K or less, and even more preferably 35 ppm/K or less. In this regard, it is to be noted that the CTE of the resin film A is obtained with a thermal mechanical analyzer (TMA). Specifically, the coefficient of thermal expansion (CTE) of the resin film A is measured by using the method in the Examples.

In addition, a glass transition temperature (Tg) of the resin film A is preferably 300° C. or more, more preferably 350° C. or more, and even more preferably 400° C. or more. In this regard, it is to be noted that the Tg of the resin film A is obtained with a thermal analyzer.

By respectively setting the CTE and the Tg to fall within the ranges described above, it is possible to reliably suppress or prevent warpage in the substrate including the base member 500 and the resin film A. Therefore, it is possible to improve a yield ratio of the organic EL display device 1 or the sensor element 10 obtained by using such a substrate.

Further, a tension strength of the resin film A is preferably 200 MPa or more, more preferably 250 MPa or more, and even more preferably 300 MPa or more. A moisture absorption ratio of the resin film A under the conditions of 69° C. and 50% RH is preferably 2% or less, more preferably 1.5% or less, and even more preferably 1% or less. By respectively setting the tension strength and the moisture absorption ratio of the resin film A to satisfy the above conditions, it is possible for the resin film A to more reliably provide the function as the foundation layer in the organic EL display device 1 or the sensor element 10.

In the case where the resin film A contains the inorganic filler, an amount of the inorganic filler contained in the resin film A is preferably in the range of to 50 volume %, more preferably in the range of 2 to 40 volume %, and even more preferably in the range of 3 to 30 volume %, with respect to the volume of the resin film A. By adding the inorganic filler to the resin film A in the above amount, it is possible to easily set the CTE of the resin film A to fall within the range described above. In this regard, a volume conversion of the resin film A and/or a volume conversion of the inorganic filler can be respectively calculated from component usages at the time of preparing the resin composition, or they can be also obtained by measuring the volume of the resin film A.

Further, an average thickness of the resin film A is not particularly limited a specific value, but is preferably 50 μm or less, more preferably 30 μm or less, and even more preferably 20 μm or less. In addition, the average thickness is preferably 1 μm or more, more preferably 2 μm or more, and even more preferably 3 μm or more. By using the resin film A having the above average thickness, it is possible for the resin film A to reliably provide the function as the foundation layer in the organic EL display device 1 or the sensor element 10. Further, it is possible to reliably suppress or prevent cracks from generating in the resin film A.

Although the descriptions have been made on the resin composition, the method of manufacturing the resin composition, the substrate and the method of manufacturing the electronic device of the present invention based on the embodiments, the present invention is not limited thereto.

For example, in the resin composition and the substrate of the present invention, each element may be replaced with an arbitrary one capable of providing the same function. Alternatively, an arbitrary component may be added to them.

Further, in the method of manufacturing the electronic device of the present invention, one or more steps may be further added for the arbitrary purpose.

Further, in the above embodiments, the method of manufacturing the electronic device of the present invention is used to manufacture the organic EL display device or the sensor element 10. However, the method of manufacturing the electronic device of the present invention is not limited thereto. For example, the method of the manufacturing the electronic device of the present invention may be used to not only manufacture other display devices such as a liquid crystal display device, but also manufacture various kinds of electronic devices such as an input device including a sensor element as the electronic element, a display device including a display element as the electronic element, an optical device including an optical element as the electronic element and a solar cell including a photoelectric conversion element as the electronic element. Further, examples of the electronic elements include not only the thin-film transistor and the photodiode but also light emitting devices such as an organic EL device, a photoelectric conversion element and a piezoelectric element.

### EXAMPLES

Hereinafter, the present invention will be described based on specific examples in detail.

1. Preparation of Resin Composition and Formation of Resin Film

### Example 1

### Preparation of Resin Composition

<1> PFMB (3.2024 g, 0.01 mol) and dry DMAc (45 ml) were added to a 250 ml three necked round bottom flask, which is equipped with a mechanical stirrer, a nitrogen inlet and outlet, and then the PFMB was completely dissolved in order to obtain a solution.

<2> Next, after the solution was cooled to 0° C., IPC (0.6395 g, 0.003 mol) was added into the solution at room temperature, and the flask wall was washed with DMAc (1.5 ml). After 15 minutes, TPC (1.4211 g, 0.007 mol) was added to the solution, and the flask wall was again washed with DMAc (1.5 ml).

<3> Next, after the solution quickly became quite viscous and formed a gel, PrO (1.4 g, 0.024 mol) was added to the gel (solution). At this time, the gel slowly broke up to form a viscous and homogenous solution.

<4> Next, after the solution was stirred for 4 hours, TA (0.225 g) was added to the solution, and then the solution was stirred for more 2 hours.

By taking the steps as described above, prepared was a resin composition (polymer solution) containing 5% of the TA (weight ratio with respect to polymer) and the aromatic polyamide (polymer) produced by the TPC, the IPC and the PFMB (mixing ratio=70 mol %/30 mol %/100 mol %).

[Formation of Resin Film (Polyamide Film)]

A resin film was formed on a glass substrate by using the prepared resin composition.

That is, first, the resin composition was applied onto a flat glass substrate (10 cm×10 cm, “EAGLE XG” produced by Corning Inc., U.S.A.), and then planarized with a doctor blade. In this way, the resin composition was formed into a film having a uniform thickness.

Next, the obtained film (resin composition) was dried at 60° C. for a few minutes under a reduced pressure. Thereafter, the temperature was raised from 60° C. to 200° C. The film was dried by keeping the temperature of 200° C. for 1 hour under a nitrogen gas flow.

Next, the dried film was subjected to a curing treatment by heating it at a temperature of near the Tg of the aromatic polyamide, that is, 330° C. for a few minutes under vacuum atmosphere or inert atmosphere. By doing so, a resin film was formed on the glass substrate.

In this regard, a thickness of the obtained resin film was about 10 μm.

### Example 2

A resin composition (polymer solution) of the Example 2 was prepared in the same manner as the Example 1, except that the following points were changed. Prior to the step <4>, the produced aromatic polyamide was re-precipitated as a fibrous precipitate by adding methanol to the solution. The precipitate was collected with a filtration, washed with methanol, and then dried. Thereafter, the obtained dried product (aromatic polyamide) was re-dissolved into the DMAc, to thereby prepare a 10% aromatic polyamide solution. Then, TA (0.225 g) was added to the solution, and the solution was stirred for more 2 hours as the step <4>. Thereafter, a resin film was formed on the glass substrate by using the resin composition in the same manner as the Example 1.

In this regard, a thickness of the obtained resin film was about 10 μm.

### Example 3

A resin composition (polymer solution) of the Example 3 was prepared in the same manner as the Example 2, except that the combination of IPC and TPC was changed to a combination of IPC (0.6395 g, 0.003 mol) and NDC (1.7097 g, 0.007 mol) in the step <2>. Thereafter, a resin film was formed on the glass substrate by using the resin composition in the same manner as the Example 1.

In this regard, a thickness of the obtained resin film was about 10 μm.

### Comparative Example

A resin composition (polymer solution) of the Comparative Example was prepared in the same manner as the Example 1, except the step <4>, that is, the addition of the TA (0.225 g) to the resin composition was omitted.

In this regard, a thickness of the obtained resin film was about 10 μm.

2. Evaluation

The resin film obtained from the resin composition of each of the Examples and the Comparative Example was evaluated in accordance with the following methods.

[Glass Transition Temperature (Tg)]

A glass transition temperature (Tg) of the resin film was measured by using a thermal mechanical analyzer (“TMA4000SA” produced by BrukerAXS Corporation).

[Total Light Transmittance (Wavelengths of 355 nm and 400 nm)]

Total light transmittances of the resin film in the wavelengths of 355 nm and 400 nm were obtained by using a spectral photometer (“UV 2450” produced by Shimadzu Corporation).

[Coefficient of Thermal Expansion (CTE)]

A coefficient of thermal expansion (CTE) was obtained as an average coefficient of thermal expansion measured as follows.

In the thermal mechanical analyzer “TMA4000SA” produced by BrukerAXS Corporation, a temperature was raised from 30° C. to 300° C. at a rate of 10° C. per 1 minute under nitrogen atmosphere. Then, the temperature was hold at 300° C. for 30 minutes. Thereafter, when the temperature was cooled to 25° C. at a rate of 10° C. per 1 minute, the average coefficient of thermal expansion was measured at the time of cooling. A width of a sample was set to 5 mm and a load was set to 2 g. The measurement was carried out in a tension mode. The average coefficient of thermal expansion was calculated with the following scheme (equation).

Average Coefficient of Thermal Expansion (ppm/K)=((L₃₀₀-L₃₀)/L₃₀)/(300−30)×10⁶,

L₃₀₀: a sample length at a temperature of 300° C.

L₃₀: a sample length at a temperature of 30° C.

[Solvent Resistance]

Solvent resistance of the resin film was evaluated by using NNP as an organic solvent. The film was immersed into the organic solvent, and then dissolving and swelling of the resin film and warpage and damage of a surface thereof were observed. The resin film in which they were not observed was defined by “A”, and the resin film in which they were observed was defined by “B”.

The evaluation results of the resin film obtained from the resin composition prepared in each of the Examples and Comparative Example as described above were shown in Table 1 below, respectively.

TABLE 1

| | Resin Composition | | | | | | | | | | | | | |
|---|---|---|---|---|---|---|---|---|---|---|---|---|---|---|
| | | | | | Aromatic | | | | | | | | | |
| | | | | | multi- | | | | | | | | | |
| | | | | | functional | | | Resin film | | | | | | |
| | Diamine | Dichloride | | | compound | Cure | | Thick- | Transparency | | | | Solvent | |
| | PFMB | IPC | TPC | NDC | TA | Temp. | Time | ness | 355 nm | 400 nm | 550 nm | CTE | resis- | Tg |
| | mol % | mol % | mol % | mol % | phr | ° C. | min | μm | % | % | % | ppm/K | tance | ° C. |
| Ex. 1 | 100 | 30 | 70 | 0 | 5 | 330 | 30 | 10.1 | 8.0 | 83.2 | 89.1 | 33.8 | A | 380 |
| Ex. 2 | 100 | 30 | 70 | 0 | 5 | 330 | 30 | 10.2 | 9.2 | 85.3 | 89.2 | 34.0 | A | 380 |
| Ex. 3 | 100 | 30 | 0 | 70 | 5 | 350 | 30 | 10.5 | 0.8 | 79.0 | 87.2 | 48.1 | A | 363 |
| Comp. Ex. | 100 | 100 | 0 | 0 | 0 | 330 | 30 | 9.8 | 60 | 85 | 89 | 53 | B | 343 |

As shown in Table 1, in each of the resin films obtained in the Examples, the total light transmittance thereof in the wavelength of 400 nm was 70% or more, the total light transmittance thereof in the wavelength of 550 nm was 80 or more, the coefficient of thermal expansion (CTE) thereof was small, and the solvent resistance thereof was excellent.

In contrast, sufficient results were not obtained in the resin film obtained in the Comparative Example.

What is claimed is:

1. A resin composition comprising:
an aromatic polyamide;
an aromatic multifunctional compound having two or more functional groups including a carboxyl group or an amino group; and
a solvent dissolving the aromatic polyamide.

2. The resin composition according to claim 1, wherein each of the functional groups of the aromatic multifunctional compound is the carboxyl group.

3. The resin composition according to claim 2, wherein the aromatic multifunctional compound is selected from the group consisting of compounds represented by the following general formulas (A) to (C): 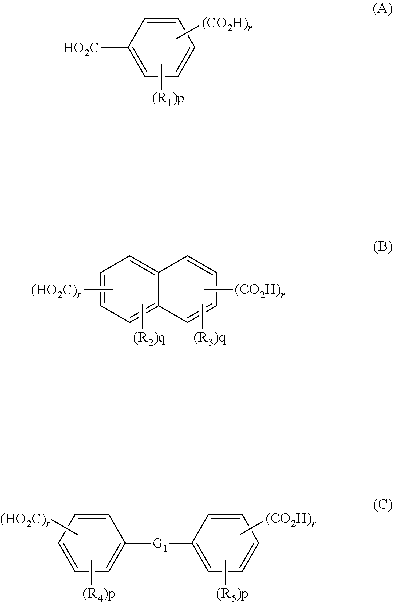
where r=1 or 2, p=3 or 4, q=2 or 3, each of R₁, R₂, R₃, R₄ and R₅ is selected from the group consisting of a hydrogen atom, a halogen (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).

4. The resin composition according to claim 3, wherein the aromatic multifunctional compound is trimeric acid.

5. The resin composition according to claim 1, wherein the aromatic polyimide is a wholly aromatic polyimide.

6. The resin composition according to claim 1, wherein the aromatic polyimide has a repeating unit represented by the following general formula (I): 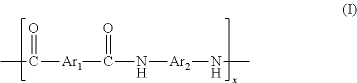
where x is an integral number of 1 or more, Ar₁ is represented by the following general formula (II), (III) or (IV): 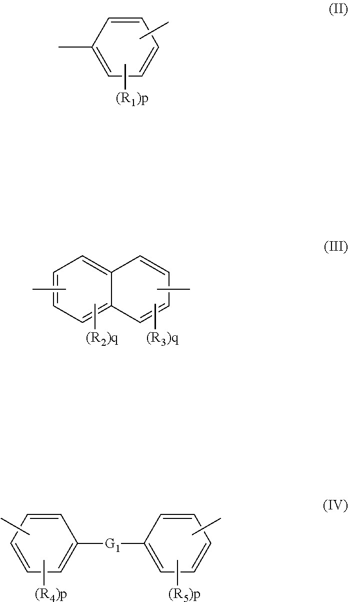
(where p=4; q=3; each of R₁, R₂, R₃, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), and Ar₂ is represented by the following general formula (V) or (VI): 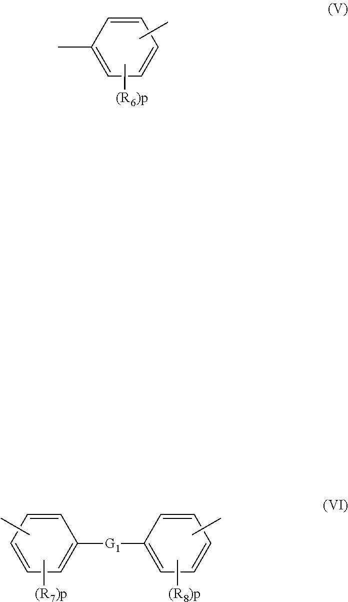
(where p=4; each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₂ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, a SO₂ group, a Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

7. The resin composition according to claim 1, wherein the resin composition is used to form a layer, and a total light transmittance of the layer in a wavelength of 355 nm is 10% or less.

8. The resin composition according to claim 7, wherein the aromatic polyimide contains a naphthalene structure.

9. The resin composition according to claim 1, wherein at least one terminal of the aromatic polyamide is end-capped.

10. The resin composition according to claim 1, wherein the solvent is a polar solvent.

11. The resin composition according to claim 1, wherein the solvent is an organic solvent and/or an inorganic solvent.

12. The resin composition according to claim 1, wherein the resin composition further contains an inorganic filler.

13. A method of manufacturing a resin composition, comprising:
mixing one or more aromatic diamines with a solvent to obtain a mixture;
reacting an aromatic diacid dichloride with the aromatic diamines by adding the aromatic diacid dichloride into the mixture to produce a solution containing an aromatic polyamide and hydrochloric acid;
removing the hydrochloric acid from the solution; and
adding an aromatic multifunctional compound having two or more functional groups including a carboxyl group or an amino group into the solution to manufacture the resin composition.

14. A substrate used for forming an electronic element thereon, comprising:
a plate-like base member having a first surface and a second surface opposite to the first surface; and
an electronic element formation layer provided at a side of the first surface of the base member and configured to be capable of forming the electronic element on the electronic element formation layer,
wherein the electronic element formation layer contains a reactant obtained by reacting an aromatic polyamide with an aromatic multifunctional compound having two or more functional groups including a carboxyl group or an amino group.

15. The substrate according to claim 14, wherein the electronic element formation layer has solvent resistance.

16. The substrate according to claim 14, wherein a coefficient of thermal expansion (CTE) of the electronic element formation layer is 100 ppm/K or less.

17. The substrate according to claim 14, wherein an average thickness of the electronic element formation layer is in the range of 1 to 50 μm.

18. The substrate according to claim 14, wherein the electronic element is an organic EL element.

19. A method of manufacturing an electronic device, comprising:
preparing a substrate, the substrate including,
a plate-like base member having a first surface and a second surface opposite to the first surface, and
an electronic element formation layer provided at a side of the first surface of the base member,
wherein the electronic element formation layer contains a reactant obtained by reacting an aromatic polyamide with an aromatic multifunctional compound having two or more functional groups including a carboxyl group or an amino group;
forming the electronic element on a surface of the electronic element formation layer opposite to the base member;
forming a cover layer so as to cover the electronic element;
irradiating the electronic element formation layer with light to thereby peel off the electronic element formation layer from the base member in an interface between the base member and the electronic element formation layer; and
separating the electronic device including the electronic element, the cover layer and the electronic element formation layer from the base member.

20. The method according to claim 19, wherein the electronic element formation layer has solvent resistance.

21. The method according to claim 19, wherein a coefficient of thermal expansion (CTE) of the electronic element formation layer is 100 ppm/K or less.

22. The method according to claim 19, wherein an average thickness of the electronic element formation layer is in the range of 1 to 50 μm.

23. The method according to claim 19, wherein the aromatic multifunctional compound is selected from the group consisting of compounds represented by the following general formulas (A) to (C): 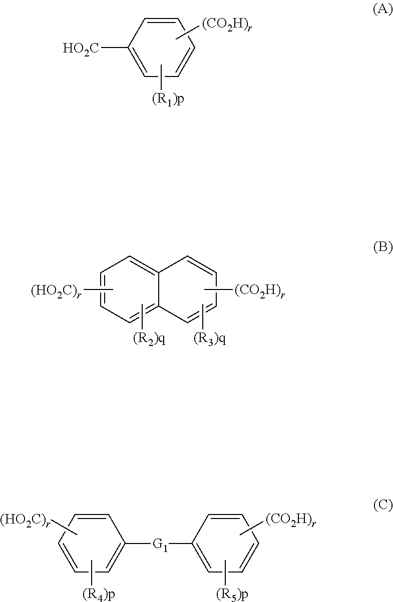
where r=1 or 2, p=3 or 4, q=2 or 3, each of R₁, R₂, R₃, R₄ and R₅ is selected from the group consisting of a hydrogen atom, a halogen (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).

24. The method according to claim 19, wherein the aromatic polyamide has a repeating unit represented by the following general formula (I): 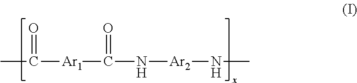
where x is an integral number of 1 or more, Ar₁ is represented by the following general formula (II), (III) or (IV): 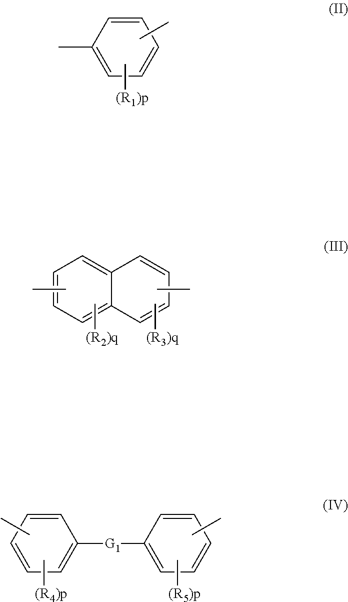
(where p=4; q=3; each of R₁, R₂, R₃, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), and Ar₂ is represented by the following general formula (V) or (VI): 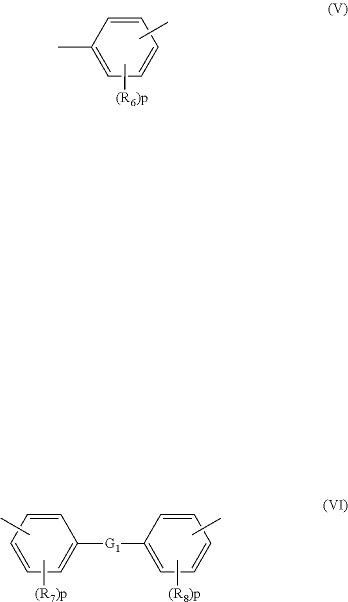
(where p=4; each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₂ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, a SO₂ group, a Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

25. An electronic device manufactured by using the method defined by claim 19.
